(19) United States
(12) Patent Application Publication
(10) Pub. No.: US 2009/0283896 A1
(43) Pub. Date: Nov. 19, 2009

(54) Package structure and method

(76) Inventor: Yu-Lin Yang, Zhuhei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/453,405

(22) Filed: May 11, 2009

(30) Foreign Application Priority Data
May 13, 2008 (TW) 097117612

(51) Int. Cl. H01L 23/498; H01L 21/98; H01L 21/56

(52) U.S. Cl. 257/692; 438/107; 438/127; 257/E21.705; 257/E21.502; 257/E23.07

(57) ABSTRACT

A semiconductor die has a surface and an active region on the surface. A thick-film coating is applied to the surface of the semiconductor die to cover only a portion or entire of the active region before the semiconductor die is cut from a wafer. The thick-film coating reduces the stress to the semiconductor die. The thick-film coating does not cover the bonding pads of the semiconductor die to avoid influencing the bonding wires bonding to the boding pads.

### FIELD OF THE INVENTION

The present invention is related generally to a package structure and method for a semiconductor device and, more particularly, to a package structure and method using thick-film coating for a single-chip or multi-chip semiconductor device.

### BACKGROUND OF THE INVENTION

A whole semiconductor production system generally involves four stages, fabrication (Fab), chip probing (CP), assembly, and final test (FT). FIG. 1 is a perspective diagram showing a conventional package structure in a single-chip semiconductor device. After the stages of Fab and CP, a semiconductor die 10 is cut from a wafer and attached on a package carrier 12. Then, bonding wires 14 are bonded to bonding pads 16 on the surface of the semiconductor die 10. Afterward, a liquid adhesive 18, generally made of polyimide (PI) nowadays, is dripped on the surface of the semiconductor die 10 to serve as a die coating. At last, the semiconductor die 10 with the die coating 18 is encapsulated by an encapsulant, for example a molded epoxy resin. To prevent the encapsulant from causing excessive stress to the surface of the semiconductor die 10 and thus resulting in product malfunction, it is preferred that the die coating 18 has a thickness greater than 15 μm. However, the existing technology cannot well control the thickness and area of the die coating 18, and thus the currently achievable maximum thickness of the die coating 18 is merely 8 μm. Moreover, the liquid adhesive 18 is dripped on the surface of the semiconductor die 10 after the wire bonding process, and thus it will smear the bonding wires 14, or even the package carrier 12. Consequently, the bonding wires 14 may come off the bonding pads 16, or gaps may be present between the encapsulant and the package carrier 12, thereby resulting in product malfunction. Further, for a semiconductor die 10 having a fuse area containing fuses therein, a laser trim area will be formed for the fuse area during the Fab stage to allow the fuses trimmed for level calibration, and moisture may penetrate through the laser trim area during the period after the Fab stage and before the assembly stage, thus damaging the fuses.

On the other hand, multi-chip module (MCM) has become a mainstream due to its smaller area and high performance. FIG. 2 is a perspective diagram showing a conventional package structure in a MCM semiconductor device using a dummy die process, in which a dummy die 22 without any function is inserted between two semiconductor dice 20 and 24 with circuit functions. However, this approach is disadvantageous because it requires additional cost of the dummy die 22. FIG. 3 is a perspective diagram showing a conventional package structure in a MCM semiconductor device using a film over wire (FOW) process, for which a film 32 is formed on the surface of the semiconductor die 34 to wrap the bonding wires 36 after bonding the wires 36 to the bonding pads on the surface of a semiconductor die 34, and then a second semiconductor die 30 is stacked on the film 32. Although this approach requires less cost, it always results in low throughput because the die attach process requires longer time. Furthermore, due to the difference between the film 32 and the bonding wires 36 under the film 32 in coefficient of thermal expansion (CTE), the bonding wires 36 are easy to fracture and break. FIG. 4 is a perspective diagram showing a conventional package structure in a MCM semiconductor device using an adhesive with ball spacers. To form this structure, an adhesive 42 containing ball spacers 44 is applied to the surface of a semiconductor die 46, and another semiconductor die 40 is further bonded thereto, with the ball spacers 44 to separate the semiconductor dice 40 and 46. However, this approach is not suitable for packaging chips with very small size. For a small size chip, due to the smaller area of the semiconductor die 46, the adhesive 42 on the surface of the semiconductor die 46 may only contain one ball spacer 44 and consequently the semiconductor die 40 tilts.

### SUMMARY OF THE INVENTION

An object of the present invention is to provide a package structure and method for a single-chip semiconductor device.

Another object of the present invention is to provide a package structure and method for a MCM semiconductor device.

According to the present invention, a package method comprises spin-coating a thick-film coating on a wafer before a semiconductor die is cut from the wafer. The thick-film coating covers only a portion or entire of an active region on a surface of the semiconductor die, and a laser trim area within the active region is completely covered by the thick-film coating. Preferably, the thick-film coating includes a silicon rubber and has a thickness greater than 15 μm, and more preferably, ranging between 15 μm and 100 μm. Then, bonding pads on the surface of the semiconductor die are exposed by removing the portion of the thick-film coating on the bonding pads by photolithography. After the semiconductor die is cut from the wafer and attached on a package carrier, bonding wires are bonded to the bonding pads, and the semiconductor die with the thick-film coating is encapsulated by an encapsulant. For MCM applications, another semiconductor die is stacked on the first semiconductor die with the thick-film coating therebetween.

### BRIEF DESCRIPTION OF THE DRAWINGS

These and other objects, features and advantages of the present invention will become apparent to those skilled in the art upon consideration of the following description of the preferred embodiments of the present invention taken in conjunction with the accompanying drawings, in which:

FIG. 1 is a perspective diagram showing a conventional package structure in a single-chip semiconductor device;

FIG. 2 is a perspective diagram showing a conventional package structure using a dummy die process;

FIG. 3 is a perspective diagram showing a conventional package structure using a FOW process;

FIG. 4 is a perspective diagram showing a conventional package structure using an adhesive with ball spacers;

FIG. 5 is a perspective diagram showing a wafer including semiconductor dice to be cut therefrom;

FIG. 6 is a perspective diagram showing a thick-film coating applied to the wafer of FIG. 5;

FIG. 7 is a perspective diagram showing a top view and a cross-sectional view of a semiconductor die cut from the wafer of FIG. 6;

FIG. 8 is a perspective diagram showing the semiconductor die of FIG. 7 attached on a package carrier;

FIG. 9 is a perspective diagram showing a finished package structure in a single-chip semiconductor device; and

FIG. 10 is a perspective diagram showing a finished package structure in a MCM semiconductor device.

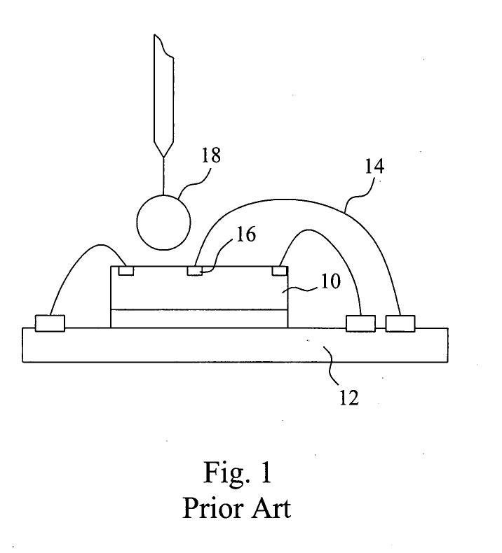

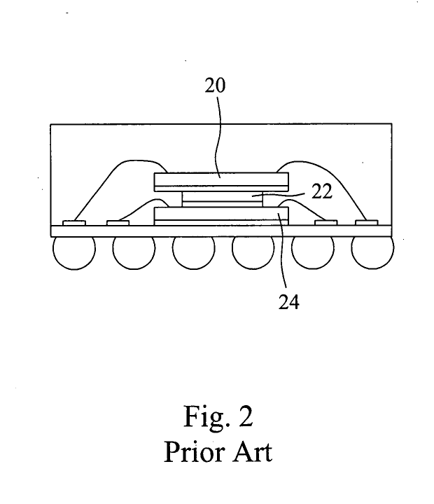

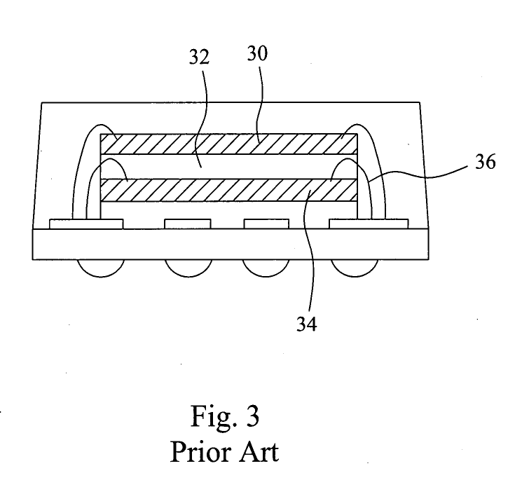

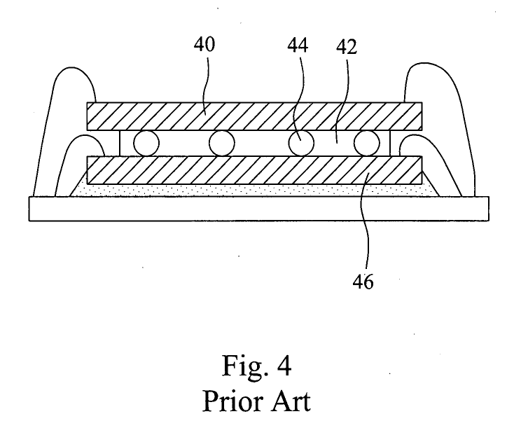

### DETAILED DESCRIPTION OF THE INVENTION

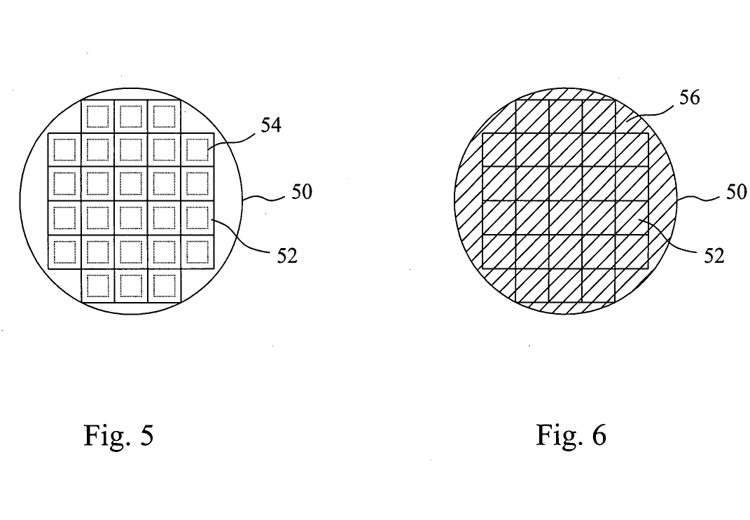

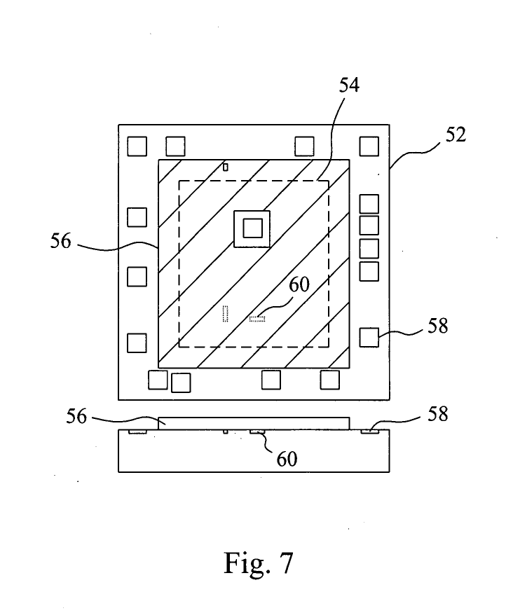

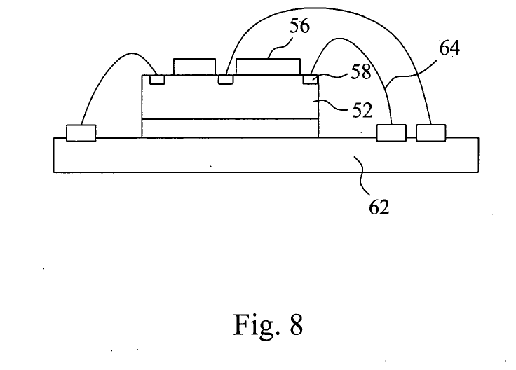

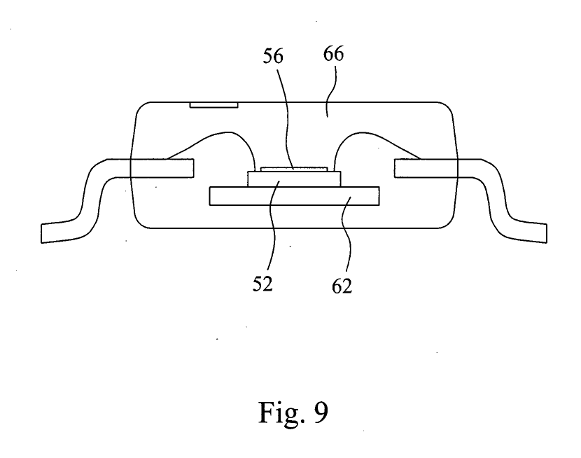

As shown in FIG. 5, after the Fab stage, a wafer 50 will include dice 52 which will be cut from the wafer 50 after the CP stage. According to the present invention, as shown in FIG. 6, a thick-film coating 56 is applied to the wafer 50, and after the dicing process, as shown in FIG. 7, the thick-film coating 56 will cover only a portion of the surface of the semiconductor die 52, and the bonding pads 58 will not be covered by the thick-film coating 56. Referring to FIGS. 5 and 7, after the circuit manufacture of the dice 52 is completed, each semiconductor die 52 has an active region 54 on the surface of this semiconductor die 52, and a laser trim process will be applied to trim the fuses within the active region 54 through a laser trim area 60. Then, referring to FIGS. 6 and 7, the thick-film coating 56 is spin-coated on the wafer 50. In an embodiment, the thick-film coating 56 includes a silicon rubber, and has a thickness greater than 15 μm, more preferably, ranging between 15 μm and 100 μm. Since the spin-coating process for the thick-film coating 56 is applied under a relatively low temperature, adverse effects caused by thermal stress can be avoided. After spin coating the thick-film coating 56, photolithography is applied to expose the bonding pads 58 on each semiconductor die 52. Then, the semiconductor dice 52 are cut from the wafer 50. In each semiconductor die 52, the thick-film coating 56 may cover only a portion of the active region 54, or entire of the active region 54 as shown in FIG. 7. The thick-film coating 56 does not cover the bonding pads 58 and thus it will prevent the semiconductor die 52 from the problems caused by CTE difference after the semiconductor die 52 is completely packaged. The laser trim area 60 within the active region 54 is completely covered by the thick-film coating 56, and thus moisture is blocked from entering through the laser trim area 60. For single-chip applications, referring to FIG. 8, the semiconductor die 52 is attached on a package carrier 62, for example a leadframe, and then bonding wires 64 are bonded to the bonding pads 58 on the surface of the semiconductor die 52. Since the bonding pads 58 on the semiconductor die 52 are not covered by the thick-film coating 56, and neither are the bonding wires 64, the bonding wires 64 will not come off the bonding pads 58 easily. After the wire bonding process, the semiconductor die 52 and the thick-film coating 56 are encapsulated by an encapsulant 66, as shown in FIG. 9. According to the present invention, the thick-film coating 56 covering the active region 54 of the semiconductor die 52 could be thicker than 15 μm, and thus adverse effects caused by stress from the encapsulant 66 can be reduced.

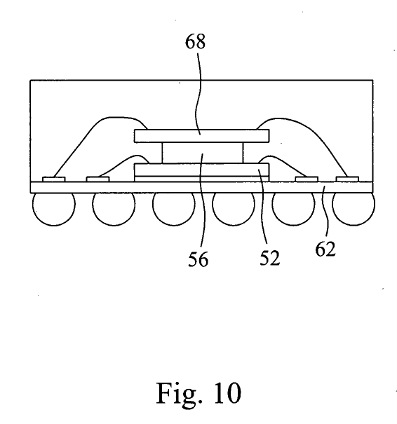

For MCM applications, FIG. 10 is a perspective diagram of an embodiment. The laser trim process and the spin-coating of the thick-film coating 56 are the same as in the previous embodiment, and after the semiconductor die 52 cut from the wafer 50 is attached on a package carrier 62, for example a printed circuit board or a MCM substrate, another semiconductor die 68 is stacked on the semiconductor die 52 with the thick-film coating 56 therebetween. The thickness of the thick-film coating 56 is controlled during the spin-coating process in such a way that there is sufficient space between the semiconductor dice 52 and 68 for wire bonding. Stacking semiconductor dice with the thick film coating 56 therebetween has less cost than the dummy die process, avoids the problems caused by CTE difference because the thick-film coating 56 does not cover the bonding wires, and is applicable to small dice package.

While the present invention has been described in conjunction with preferred embodiments thereof, it is evident that many alternatives, modifications and variations will be apparent to those skilled in the art. Accordingly, it is intended to embrace all such alternatives, modifications and variations that fall within the spirit and scope thereof as set forth in the appended claims.

What is claimed is:

1. A package method, comprising:
providing a first semiconductor die having a surface and a thick-film coating on only a portion of the surface; and
stacking a second semiconductor die on the first semiconductor die with the thick-film coating therebetween.

2. The package method of claim 1, wherein the thick-film coating comprises a silicon rubber.

3. The package method of claim 1, wherein the thick-film coating has a thickness greater than 15 μm.

4. The package method of claim 1, wherein the thick-film coating has a thickness ranging between 15 μm and 100 μm.

5. The package method of claim 1, further comprising bonding a wire to a bonding pad on the surface of the first semiconductor die before stacking the second semiconductor die on the first semiconductor die, wherein the bonding pad is not covered by the thick-film coating.

6. The package method of claim 1, further comprising encapsulating the two semiconductor dice and the thick-film coating with an encapsulant.

7. A package method, comprising:
providing a wafer including a first semiconductor die to be cut from the wafer;
spin-coating a thick-film coating on the wafer to cover only a portion of a surface of the first semiconductor die;
cutting the first semiconductor die from the wafer; and
stacking a second semiconductor die on the first semiconductor die with the thick-film coating therebetween.

8. The package method of claim 7, wherein the thick-film coating comprises a silicon rubber.

9. The package method of claim 7, wherein the thick-film coating has a thickness greater than 15 μm.

10. The package method of claim 7, wherein the thick-film coating has a thickness ranging between 15 μm and 100 μm.

11. The package method of claim 7, further comprising bonding a wire to a bonding pad on the surface of the first semiconductor die before stacking the second semiconductor die on the first semiconductor die, wherein the bonding pad is not covered by the thick-film coating.

12. The package method of claim 7, further comprising encapsulating the two semiconductor dice and the thick-film coating with an encapsulant.

13. A package method, comprising:
providing a wafer including a semiconductor die to be cut from the wafer, wherein the semiconductor die has a surface and an active region on the surface; and
spin-coating a thick-film coating on the wafer to cover only a portion or entire of the active region.

14. The package method of claim 13, wherein the thick-film coating comprises a silicon rubber.

15. The package method of claim 13, wherein the thick-film coating has a thickness greater than 15 μm.

16. The package method of claim 13, wherein the thick-film coating has a thickness ranging between 15 μm and

17. The package method of claim 13, further comprising:
cutting the semiconductor die from the wafer; and
bonding a wire to a bonding pad on the surface of the semiconductor die after the semiconductor die is cut from the wafer, wherein the bonding pad is not covered by the thick-film coating.

18. The package method of claim 17, further comprising molding an encapsulant to encapsulate the semiconductor die and the thick-film coating.

19. The package method of claim 13, further comprising:
cutting the semiconductor die from the wafer;
attaching the semiconductor die on a package carrier after it is cut from the wafer; and
bonding a wire to a bonding pad on the surface of the semiconductor die after the semiconductor die is attached on the package carrier, wherein the bonding pad is not covered by the thick-film coating.

20. The package method of claim 19, further comprising encapsulating the semiconductor die and the thick-film coating with an encapsulant.

21. A package structure, comprising:
a first semiconductor die having a surface;
a thick-film coating on only a portion of the surface of the first semiconductor die; and
a second semiconductor die stacking on the first semiconductor die with the thick-film coating therebetween.

22. The package structure of claim 21, wherein the thick-film coating comprises a silicon rubber.

23. The package structure of claim 21, wherein the thick-film coating has a thickness greater than 15 μm.

24. The package structure of claim 21, wherein the thick-film coating has a thickness ranging between 15 μm and 100 μm.

25. The package structure of claim 21, wherein the first semiconductor die has a bonding pad on the surface and is not covered by the thick-film coating.

26. The package structure of claim 21, wherein the first semiconductor die comprises:
a bonding pad on the surface; and
a bonding wire connected to the bonding pad and not covered by the thick-film coating.

27. The package structure of claim 21, further comprising:
a package carrier having the first semiconductor die attached thereon; and
an encapsulant encapsulating the two semiconductor dice and the thick-film coating.

28. A package structure, comprising:
a semiconductor die having a surface and an active region on the surface; and
a thick-film coating covering only a portion or entire of the active region.

29. The package structure of claim 28, wherein the thick-film coating comprises a silicon rubber.

30. The package structure of claim 28, wherein the thick-film coating has a thickness greater than 15 μm.

31. The package structure of claim 28, wherein the thick-film coating has a thickness ranging between 15 μm and 100 μm.

32. The package structure of claim 28, wherein the semiconductor die has a laser trim area within the active region and completely covered by the thick-film coating.

33. The package structure of claim 28, wherein the semiconductor die comprises a bonding pad on the surface and is not covered by the thick-film coating.

34. The package structure of claim 28, wherein the semiconductor die comprises:
a bonding pad on the surface; and
a bonding wire connected to the bonding pad and not covered by the thick-film coating.

35. The package structure of claim 28, further comprising an encapsulant encapsulating the semiconductor die and the thick-film coating.

36. The package structure of claim 28, further comprising a package carrier having the semiconductor die attached thereon.

37. The package structure of claim 36, further comprising an encapsulant encapsulating the semiconductor die and the thick-film coating.
